(19) United States
(12) Patent Application Publication
(10) Pub. No.: US 2010/0003623 A1
(43) Pub. Date: Jan. 7, 2010

(54) METHOD OF PATTERNING MULTIPLE PHOTOSENSITIVE LAYERS

(75) Inventor: Yan-Hsiu Liu, Tainan City (TW)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/167,473

(22) Filed: Jul. 3, 2008

(51) Int. Cl. G03F 7/20

(52) U.S. Cl. 430/326; 430/325

(57) ABSTRACT

A method of patterning multiple photosensitive layers is provided. A first photosensitive layer is formed on a substrate. The first photosensitive layer is exposed by using a first mask. A second photosensitive layer is formed on the first photosensitive layer. The second photosensitive layer is exposed by using a second mask, wherein the second mask is different from the first mask. A first development process is performed to the exposed first and second photosensitive layers to form a plurality of patterns on the substrate.

### BACKGROUND OF THE INVENTION

1. Field of Invention

The present invention relates to a semiconductor fabrication method, and more particularly, to a method of patterning multiple photosensitive layers.

2. Description of Related Art

In a lithography process, the method of forming a patterned photoresist layer includes spin coating a photoresist layer on a substrate, and then performing an exposure-and-development process.

Conventionally, the patterned photoresist layer is used as an etching mask or ion implant mask, so there is no special requirement for the photoresist profile. However, as the rapid development of semiconductor devices, the conventional photoresist pattern having a rectangle profile cannot meet the production requirement anymore. For example, a photoresist pattern having an inverted trapezoid profile is required in a lift-off process for fabricating a back-end interconnection of a micro-electro-mechanical device. Further, the request of customers for fabricating a special photoresist profile is often met in recent years.

Therefore, to fabricate a photoresist pattern having a special profile with the existing manufacturing equipment has become one of the main topics in the industry.

### SUMMARY OF THE INVENTION

The present invention provides a method of patterning multiple photosensitive layers, in which a photoresist pattern having a special profile can be fabricated by performing a simple process.

The present invention provides a method of patterning multiple photosensitive layers. A first photosensitive layer is formed on a substrate. The first photosensitive layer is exposed by using a first mask. A second photosensitive layer is formed on the first photosensitive layer. The second photosensitive layer is exposed by using a second mask, wherein the second mask is different from the first mask. A first development process is performed to the exposed first and second photosensitive layers to form a plurality of patterns on the substrate.

According to an embodiment, the first photosensitive layer and the second photosensitive layer comprise photoresist materials of the same photosensitive type.

According to an embodiment, the first photosensitive layer and the second photosensitive layer respectively comprise a positive photoresist material.

According to an embodiment, the first photosensitive layer and the second photosensitive layer respectively comprise a negative photoresist material.

According to an embodiment, the first photosensitive layer and the second photosensitive layer comprise color photoresist materials.

According to an embodiment, colors of the first photosensitive layer and the second photosensitive layer comprise two of red, green, blue, cyan, magenta, yellow and black.

According to an embodiment, after the step of exposing the second photosensitive layer and before the step of performing the first development process, the method of patterning multiple photosensitive layers further includes forming a third photosensitive layer on the second photosensitive layer, and using a third mask to expose the third photosensitive layer, wherein the third mask is different from the first mask and the second mask.

According to an embodiment, the method of patterning multiple photosensitive layers further includes performing the first development process to the exposed third photosensitive layer.

According to an embodiment, the first photosensitive layer, the second photosensitive layer and the third photosensitive layer comprise photoresist materials of the same photosensitive type.

According to an embodiment, the first photosensitive layer, the second photosensitive layer and the third photosensitive layer respectively comprise a positive photoresist material.

According to an embodiment, the first photosensitive layer, the second photosensitive layer and the third photosensitive layer respectively comprise a negative photoresist material.

According to an embodiment, the first photosensitive layer, the second photosensitive layer and the third photosensitive layer comprise color photoresist materials.

According to an embodiment, colors of the first photosensitive layer, the second photosensitive layer and the third photosensitive layer comprise red, green, blue, cyan, magenta, yellow and black.

According to an embodiment, at least a part of each of the patterns comprises a profile with a bottom width greater than a top width.

According to an embodiment, at least a part of each of the patterns comprises a profile with a bottom equal to a top width.

According to an embodiment, at least a part of each of the patterns comprises a profile with a bottom width smaller than a top width.

According to the method of patterning multiple photosensitive layers of the present invention, a photoresist pattern with a T-shaped profile as well as a black matrix and a customized color of a color filter can be easily obtained by performing multiple coatings of photoresist materials of the same photosensitive type, multiple exposures with different masks and a single development process. Therefore, the cost is greatly saved and the competitiveness is significantly improved.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a flow chart of steps in a method of patterning multiple photosensitive layers according to a first embodiment of the present invention.

FIGS. 1A to 1E schematically illustrate, in a cross-section view, a method of patterning multiple photosensitive layers according to a first embodiment of the present invention.

FIG. 2 schematically illustrates, in a cross-section view, a method of patterning multiple photosensitive layers according to a second embodiment of the present invention.

FIG. 3 schematically illustrates a flow chart of steps in a method of patterning multiple photosensitive layers according to a third embodiment of the present invention.

FIGS. 3A to 3G schematically illustrate, in a cross-section view, a method of patterning multiple photosensitive layers according to a third embodiment of the present invention.

### DESCRIPTION OF EMBODIMENTS

### First Embodiment

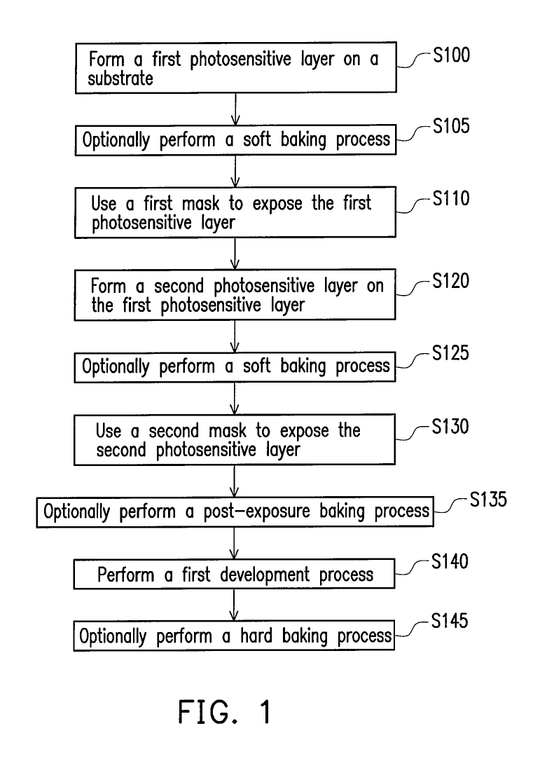

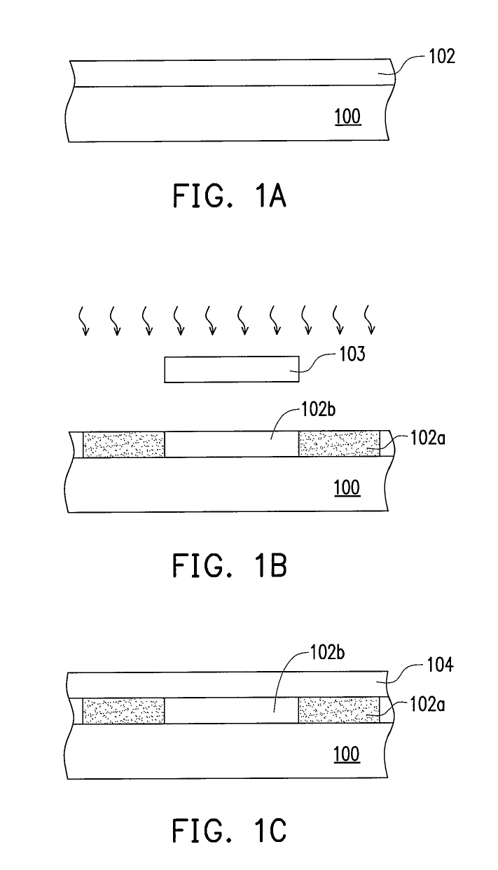

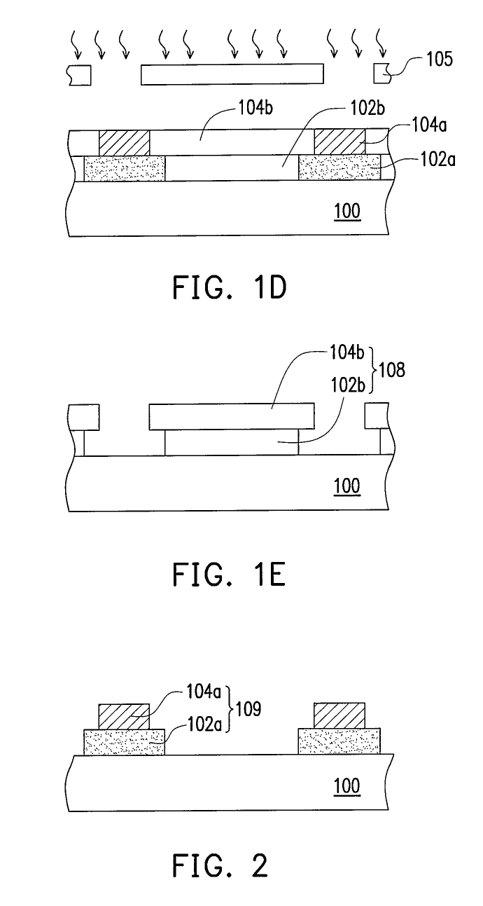

FIG. 1 schematically illustrates a flow chart of steps in a method of patterning multiple photosensitive layers according to a first embodiment of the present invention. FIGS. 1A to 1E schematically illustrate, in a cross-section view, a method of patterning multiple photosensitive layers according to a first embodiment of the present invention.

Referring to FIGS. 1 and 1A, a step S100 is performed to form a first photosensitive layer 102 on a substrate 100. The first photosensitive layer 102 may include a positive photoresist material and is formed by a method of spin coating, for example.

Referring to FIGS. 1 and 1B, a step S110 is performed. In the step S110, a first exposure process is performed using a first mask 103 to the first photosensitive layer 102, so as to form exposed regions 102a and unexposed regions 102b in the second photosensitive layer 102.

Referring to FIGS. 1 and 1C, a step S120 is performed to form a second photosensitive layer 104 on the first photosensitive layer 102. The material and the method of the second photosensitive layer 104 are similar to those of the first photosensitive layer 102. For example, the second photosensitive layer 104 may also include a positive photoresist material and is formed by a method of spin coating.

Referring to FIGS. 1 and 1D, a step S130 is performed. In the step S130, a second exposure process is performed using a second mask 105 to the second photosensitive layer 104, so as to form exposed regions 104a and unexposed regions 104b in the second photosensitive layer 104. The patterns of the second mask 105 are different from those of the first mask 103.

In this embodiment, the exposed regions 104a in the second photosensitive layer 104 are formed on the exposed regions 102a in the first photosensitive layer 102, and the exposed regions 104a are smaller than the exposed regions 102a; thus, the exposed regions 102a below the exposed regions 104a is not affected when the second exposure process is performed. That is, the photoresist profile of the exposed regions 102a and 104a is substantially an inverted T-shape. Similarly, the unexposed regions 104b are formed on the unexposed regions 102b, and the unexposed regions 104b are greater than the unexposed regions 102b; thus, the unexposed regions 102b is shielded by the unexposed regions 104b when the second exposure process is performed. That is, the photoresist profile of the unexposed regions 102b and 104b is substantially a T-shape.

Referring to FIGS. 1 and 1E, a step S140 is performed. In the step S140, a first development process 150 (not shown) is performed to the exposed first and second photosensitive layers 102 and 104, so as to form a plurality of patterns 108 on the substrate 100. In this embodiment, the first photosensitive layer 102 and second photosensitive layer 104 respectively include a positive photoresist material; that is, the exposed regions 102a and 104a are dissolved in the developer while the unexposed regions 102b and 104b are not. In other words, the patterns 108 including the unexposed regions 102b and 104b remain, and the photoresist profile of the patterns 108 is substantially a T-shape; i.e. the patterns 108 each have a profile with a bottom width smaller than a top width.

It is appreciated by persons skilled in the art that the method of patterning multiple photosensitive layers according to the invention can be appropriately combined with conventional photolithography processes, such as soft baling (SB), post-exposure baking (PEB) and hard baking (HB), as long as the spirit and scope of this invention are not compromised. In an embodiment, referring to step S100 of FIG. 1, a soft baking process can be optionally performed to the first photosensitive layer 102 after the step of S100. In another embodiment, referring to step 125 of FIG. 1, another baking process can be optionally performed to the second photosensitive layer 104 after the step of S120. In another embodiment, referring to step S135 of FIG. 1, a post-exposure baking process can be optionally performed to the exposed first and second photosensitive layers 102 and 104 after the step of S130. In another embodiment, referring to step S145 of FIG. 1, a hard baking process can be optionally performed to the patterns 108 after the step of S140.

In an embodiment, the T-shaped patterns 108 formed by the patterning method of the present invention are applicable to a lift-off process for fabricating a back-end interconnection of a micro-electro-mechanical device. The process is simple and the specially controlled exposure energy and PEB temperature of the conventional method are not required.

In another embodiment, the T-shaped patterns 108 are applicable to a gradient implant of an ion implantation process. The implant concentration profile can be controlled by the special structure of the T-shaped patterns 108.

Compared to the conventional method of using a negative photoresist material, the method in accordance with the present invention is advantageous by using a positive photoresist material to form a T-shaped photoresist pattern. It is known that a positive photoresist material has a better resolution and contrast than a negative photoresist material, so that a smaller critical dimension is obtained, and the performance and the level of integration of a device are accordingly enhanced.

### Second Embodiment

FIG. 2 schematically illustrates, in a cross-section view, a method of patterning multiple photosensitive layers according to a second embodiment of the present invention.

Referring to FIG. 1, steps S100, S110, S120 and S130 are performed to form an intermediate structure of FIG. 1D. The difference between the first and second embodiments is that the first photosensitive layer 102 and the second photosensitive layer 104 respectively include a negative photoresisit material, for example.

Referring to FIGS. 1 and 2, a step 140 is performed. In the step S140, a first development process 150 (not shown) is performed to the exposed first and second photosensitive layers 102 and 104, so as to form a plurality of patterns 109. In this embodiment, the first photosensitive layer 102 and second photosensitive layer 104 respectively include a negative photoresist material; that is, the exposed regions 102a and 104a are not dissolved in the developer while the unexposed regions 102b and 104b are. In other words, the patterns 109 including the exposed regions 102a and 104a remain, and the photoresist profile of the patterns 109 is substantially an inverted T-shape; i.e. the patterns 109 respectively have a profile with a bottom width greater than a top width. The inverted T-shaped photoresist patterns 109 are suitable for fabricating a color filter. The details will be described in the third embodiment as follows.

In the first and second embodiments, the coating of two photosensitive layers is provided for illustration purposes and is not to be construed as limiting the scope of the invention. It is appreciated by persons skilled in the art that more than two photosensitive layers can be coated if necessary. Three photosensitive layers are coated to illustrate the present invention in the following embodiment.

### Third Embodiment

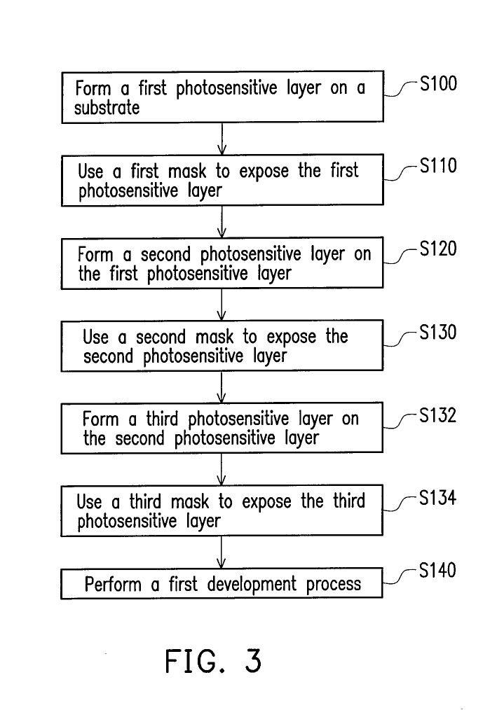

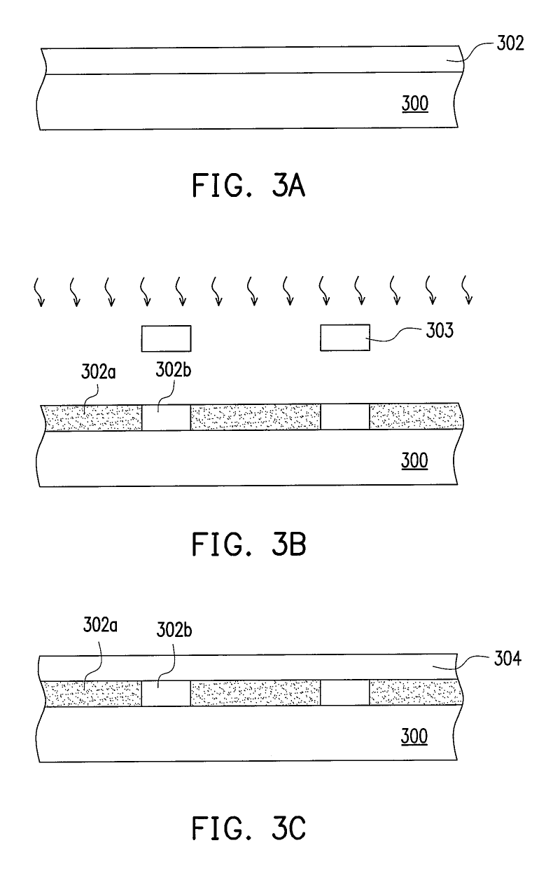

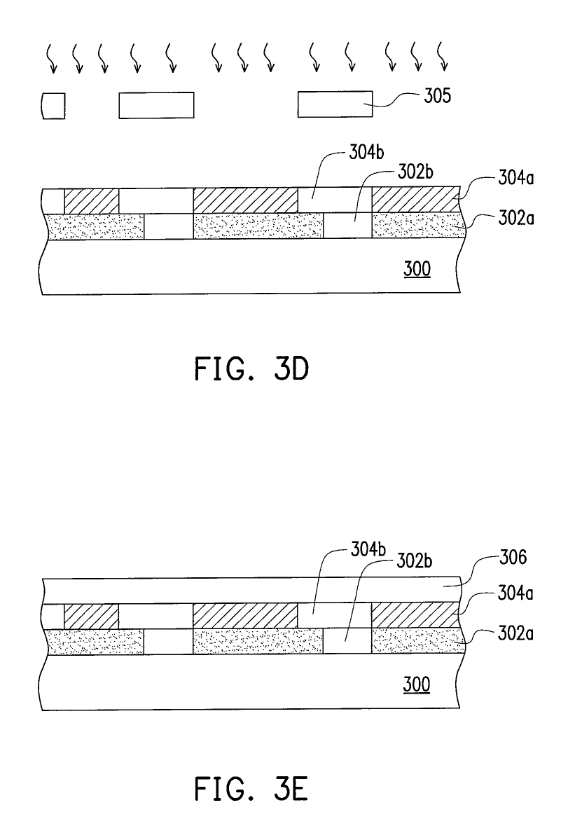

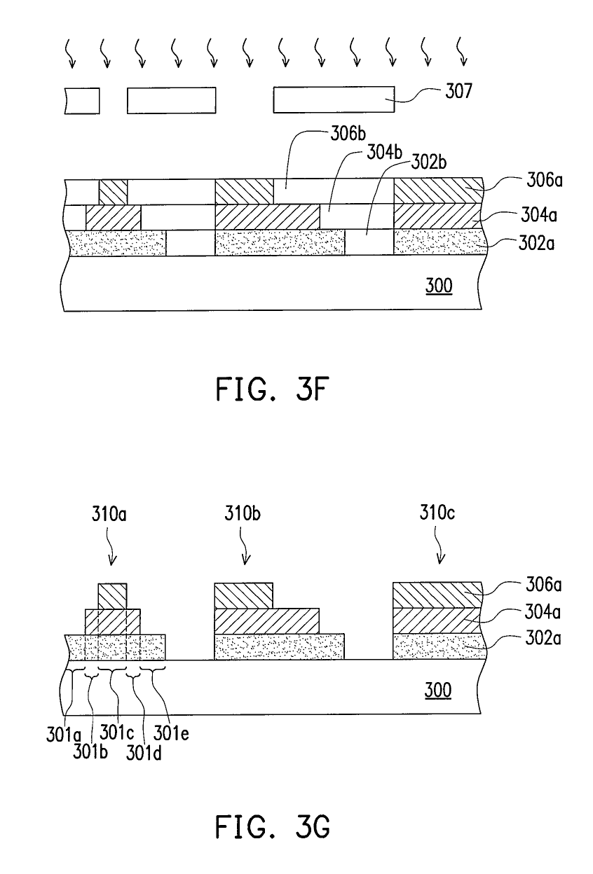

FIG. 3 schematically illustrates a flow chart of steps in a method of patterning multiple photosensitive layers according to a third embodiment of the present invention. FIGS. 3A to 3G schematically illustrate, in a cross-section view, a method of patterning multiple photosensitive layers according to a third embodiment of the present invention.

Referring to FIGS. 3 and 3A, a step S100 is performed to form a first photosensitive layer 302 on a substrate 300. The first photosensitive layer 302 may include a negative photoresist material.

Referring to FIGS. 3 and 3B, a step S110 is performed. In the step S110, the first photosensitive layer 302 is exposed by using a first mask 303, so that exposed regions 302a and unexposed regions 302b are formed in the second photosensitive layer 302.

Referring to FIGS. 3 and 3C, a step S120 is performed to form a second photosensitive layer 304 on the first photosensitive layer 302. The second photosensitive layer 304 may include a negative photoresist material.

Referring to FIGS. 3 and 3D, a step 130 is performed. In the step S130, the second photosensitive layer 304 is exposed by using a second mask 305, so that exposed regions 304a and unexposed regions 304b are formed in the second photosensitive layer 304. The second mask 305 is different from the first mask 303.

Referring to FIGS. 3 and 3E, a step S132 is performed to form a third photosensitive layer 306 on the second photosensitive layer 304. The third photosensitive layer 304 may include a negative photoresist material.

Referring to FIGS. 3 and 3F, a step S134 is performed. In the step S134, the third photosensitive layer 306 is exposed by using a third mask 307, so that exposed regions 306a and unexposed regions 306b are formed in the third photosensitive layer 306. The third mask 307 is different from the second mask 305 and the first mask 303.

Referring to FIGS. 3 and 3G, a step S140 is performed. A first development process 150 (not shown) is performed to the exposed first, second and third photosensitive layers 302, 304 and 306, so as to form a plurality of patterns 310a, 310b and 310c on the substrate 300.

In this embodiment, the first, second and third photosensitive layers 302, 304 and 306 respectively include a negative photoresist material; that is, the exposed regions 302a, 304a and 306a are not dissolved in the developer while the unexposed regions 302b, 304b and 306b are. In other words, the patterns 310a, 310b and 310c including the exposed regions 302a, 304a and 306a remain. As shown in FIG. 3G, the patterns 310a and 310b respectively have a profile with a bottom width smaller than a top width, and the pattern 310c has a profile with a bottom width equal to a top width.

The method of patterning multiple photosensitive layers according to the present invention is suitable for fabricating a color filter. The pattern 310a is taken to illustrate the present invention as follows. In the pattern 310a, a plurality of regions 310a, 310b and 310c are divided by their stacking structures.

The region 310a is a single-layer structure including a portion of the exposed region 302a in the first photosensitive layer 302. The region 310b is a double-layer structure including a portion of the exposed region 302a in the first photosensitive layer 302 and a portion of the exposed region 304a in the second photosensitive layer 304. The region 310c is a triple-layer structure including a portion of the exposed region 302a in the first photosensitive layer 302, a portion of the exposed region 304a in the second photosensitive layer 304 and a portion of the exposed region 306a in the third photosensitive layer 306.

When the first, second and third photosensitive layers 302, 304 and 306 respectively include a negative color photoresist material, the formed pattern 310a can be regarded as a color filter for a liquid crystal display device or a CMOS image sensor (CIS). In details, colors of the first, second and third photosensitive layers 302, 304 and 306 include red (R), green (G), blue (B), cyan (C), magenta (M), yellow (Y) and black (K). Therefore, a color different from three primary colors (RGB) or the complementary colors (CMY) of three primary colors can be easily obtained by stacking the color photoresist layers with commercially available colors, such as CMY, RGB, or black, and fine tuning the thickness and forming sequence of each layer.

In an embodiment, the first photosensitive layer 302 is a cyan color photoresist layer, the second photosensitive layer 304 is a magenta color photoresist layer and the third photosensitive layer 306 is a yellow color photoresist layer. When the complementary colors (CMY) of three primary colors are mixed in equal amount, the resulting color of the triple-layer structure in the region 310c is black, and the resulting color of the double-layer structure in the region 310b is blue, and the resulting color of the single-layer structure in the region 310a is cyan. That is, a color filter including cyan, blue and black is formed by staking cyan, magenta and yellow, wherein the black portion can be used as a black matrix. The patterns 310b and 310c of the third embodiment and the patterns 109 of the second embodiment are similar to the pattern 310a; thus, the details are not further discussed.

The black matrix in accordance with the method of the present invention does not have the light-transmitting problem and the process is simple. A color filter including a black matrix is formed by stacking the existing complementary colors (CMY) of three primary colors. The cost of purchasing a black resin, and the process of coating, exposing and developing the black resin can be obviated; thus, the fabrication cost is greatly reduced and the competitiveness is significantly improved.

The mixed amounts of the complementary colors (CMY) of three primary colors can be appropriately adjusted to fabricate a customized color, just like watercolors mixing. In production, the sequence, thickness and forming sequence of the three color photoresist layers can be fine tuned to achieve the purpose of fabricating a customized color. Therefore, the cost of purchasing a customized color is saved, and the request of customers is easily met. Similarly, three primary colors RGB can be applied to fabricate a customized color, as in the case of CMY

In the present invention, not only a customized color can be fabricated, but also the special request of customers can be met. For example, a color filter for simulating human eyes can be fabricated by stacking the green and red color photoresist layers and performing a circuit computation, in which the signals of the green and red color photoresist layers are subtracted to take off the IR signal in the background.

It is appreciated by persons skilled in the art that a negative photoresist material is used to illustrate, but not limit to, the third embodiment. A positive photoresist material can be applied to fabricate photoresist patterns with a required profile upon customers' request.

In summary, the method of patterning multiple photosensitive layers in accordance with the present invention is applicable to all processes which require a non-conventional photoresist profile. For example, a photoresist pattern with a T-shaped profile formed by stacking positive photosensitive layers is applicable to a lift-off process for fabricating a back-end interconnection of a micro-electro-mechanical device or a gradient implant process of an ion implantation. Another photoresist pattern having a profile with a bottom width greater than a top width (as shown in FIG. 3G) formed by stacking negative photosensitive layers (e.g. color photoresist layers) is suitable for fabricating a black matrix or a customized color. Further, the method of patterning multiple photosensitive layers is very simple, so that the cost can be greatly saved and the competitiveness can be significantly improved.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method of patterning multiple photosensitive layers, comprising:
forming a first photosensitive layer on a substrate;
using a first mask to expose the first photosensitive layer;
forming a second photosensitive layer on the first photosensitive layer;
using a second mask to expose the second photosensitive layer, wherein the second mask is different from the first mask; and
performing a first development process to the exposed first and second photosensitive layers to form a plurality of patterns on the substrate.

2. The method of claim 1, wherein the first photosensitive layer and the second photosensitive layer comprise photoresist materials of the same photosensitive type.

3. The method of claim 2, wherein the first photosensitive layer and the second photosensitive layer respectively comprise a positive photoresist material.

4. The method of claim 2, wherein the first photosensitive layer and the second photosensitive layer respecitvely comprise a negative photoresist material.

5. The method of claim 1, wherein the first photosensitive layer and the second photosensitive layer comprise color photoresist materials.

6. The method of claim 5, wherein colors of the first photosensitive layer and the second photosensitive layer comprise two of red, green, blue, cyan, magenta, yellow and black.

7. The method of claim 1, after the step of exposing the second photosensitive layer and before the step of performing the first development process, further comprising:
forming a third photosensitive layer on the second photosensitive layer; and
using a third mask to expose the third photosensitive layer, wherein the third mask is different from the first mask and the second mask.

8. The method of claim 7, further comprising performing the first development process to the exposed third photosensitive layer.

9. The method of claim 7, wherein the first photosensitive layer, the second photosensitive layer and the third photosensitive layer comprise photoresist materials of the same photosensitive type.

10. The method of claim 9, wherein the first photosensitive layer, the second photosensitive layer and the third photosensitive layer respectively comprise a positive photoresist material.

11. The method of claim 9, wherein the first photosensitive layer, the second photosensitive layer and the third photosensitive layer respectively comprise a negative photoresist material.

12. The method of claim 7, wherein the first photosensitive layer, the second photosensitive layer and the third photosensitive layer comprise color photoresist materials.

13. The method of claim 12, wherein colors of the first photosensitive layer, the second photosensitive layer and the third photosensitive layer comprise red, green, blue, cyan, magenta, yellow and black.

14. The method of claim 1, wherein at least a part of each of the patterns comprises a profile with a bottom width greater than a top width.

15. The method of claim 1, wherein at least a part of each of the patterns comprises a profile with a bottom equal to a top width.

16. The method of claim 1, wherein at least a part of each of the patterns comprises a profile with a bottom width smaller than a top width.
